(19) United States
(12) Patent Application Publication
(10) Pub. No.: US 2010/0102880 A1
(43) Pub. Date: Apr. 29, 2010

(54) LOAD DRIVE DEVICE

(75) Inventors: Junichi MATSUBARA, Aichi (JP); Satoki URUNO, Aichi (JP); Hiroki KISHI, Aichi (JP); Yoshiharu KAWARAZAKI, Aichi (JP); Satoshi CHIKAZAWA, Aichi (JP); Takashi NAGAO, Aichi (JP)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: KABUSHIKI KAISHA TOKAI RIKA DENKI SEISAKUSHO, Aichi (JP)

(21) Appl. No.: 12/605,967

(22) Filed: Oct. 26, 2009

(30) Foreign Application Priority Data
Oct. 29, 2008 (JP) 2008-278526

(51) Int. Cl. H03F 1/52; G08B 21/00

(52) U.S. Cl. 330/207 P; 340/653

(57) ABSTRACT

A load drive device has a load drive unit including an input system electrically connectable to a control power supply and an output system electrically connectable to a load drive power supply. The load drive unit supplies the electrical load with load drive voltage from the load drive power supply via the output system when the control power supply applies control voltage to the input system. A potential difference detection unit detects a potential difference between the control voltage and the load drive voltage. A potential fixing unit fixes a potential at a control system electrical route, connecting the control power supply and the input system of the load drive unit, to a prohibition level that prohibits the output system of the load drive unit from driving the electrical load when the potential difference detected by the potential difference detection unit exceeds a predetermined threshold value.

### CROSS-REFERENCE TO RELATED APPLICATIONS

This application is based upon and claims the benefit of priority from prior Japanese Patent Application No. 2008-278526, filed on Oct. 29, 2008, the entire contents of which are incorporated herein by reference.

### BACKGROUND OF THE INVENTION

The present invention relates to a load drive device that drives an electrical load such as a lamp or a motor, and, more particularly, to a load drive device that drives a load with a plurality of power supplies including a control power supply and a load drive power supply.

When driving an electrical load having a large capacitance, two power supplies, such as a control power supply and a load drive power supply, are generally used to drive the load (refer to Japanese Laid-Open Patent Publication No. 10-22803). With such a structure, variations in the power supply voltage when the load is driven affects the load drive device less in comparison to when driving the load with a single power supply.

Referring to FIG. 1, in one of the power supplies, a control voltage VBB (i.e., the voltage from the control power supply that is applied to the load drive device) may become null or low for one reason or another. At the same time, in the other one of the power supplies, a load drive voltage VBP (i.e., the voltage from the load drive power supply that is applied to the load drive device) may not decrease like the control voltage VBB and remain at a predetermined voltage allowing for the electric circuit to be driven. In such a case, the phenomenon described below may occur.

In such a case, the existence of a stray capacitor (capacitance) increases the potential at an input terminal of a switching element, which is for driving the electrical load, even when the electrical load is not being driven, in which state the potential should be low. This may activate the switching element and drive the electrical load. Although this is a temporary phenomenon, if the electrical load were a lamp, this would momentarily turn on the lamp. If the electrical load were a motor, torque would be produced notwithstanding the fact that it may be too small to produce rotation. These situations both result from a phenomenon caused by the existence of a stray capacitor.

### SUMMARY OF THE INVENTION

The present invention provides a load drive device that prevents the occurrence of a phenomenon caused by the existence of a stray capacitor.

One aspect of the present invention is a load drive device for driving an electrical load with a control power supply and a load drive power supply. The load drive device is provided with a load drive unit including an input system electrically connectable to the control power supply and an output system electrically connectable to the load drive power supply. The load drive unit supplies the electrical load with load drive voltage from the load drive power supply via the output system when the control power supply applies control voltage to the input system. A potential difference detection unit detects a potential difference between the control voltage and the load drive voltage. A potential fixing unit fixes a potential at a control system electrical route, which connects the control power supply and the input system of the load drive unit, to a prohibition level that prohibits the output system of the load drive unit from driving the electrical load when the potential difference detected by the potential difference detection unit exceeds a predetermined threshold value.

A further aspect of the present invention provides a load drive device for driving an electrical load with a control power supply and a load drive power supply. The load drive device is provided with a load drive unit including an input system electrically connectable to the control power supply and an output system electrically connectable to the load drive power supply. The load drive unit supplies the electrical load with load drive voltage from the load drive power supply via the output system when the control power supply applies control voltage to the input system. A control voltage detection unit detects the control voltage. A potential fixing unit fixes a potential at a control system electrical route, which connects the control power supply and the input system of the load drive unit, to a prohibition level that prohibits the output system of the load drive unit from driving the electrical load when the control voltage detected by the control voltage detection unit is less than a normal control voltage.

Another aspect of the present invention is a load drive device for driving an electrical load with a control power supply and a load drive power supply. The load drive device is provided with a load drive unit including an input system electrically connectable to the control power supply and an output system electrically connectable to the load drive power supply. The load drive unit supplies the electrical load with load drive voltage from the load drive power supply via the output system when the control power supply applies control voltage to the input system. A load drive voltage detection unit detects the load drive voltage. A notification device issues a notification indicating that the load drive voltage is low when the load drive voltage detected by the load drive voltage detection unit is lower than a normal load drive voltage.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic electric circuit diagram of a load drive device in the prior art; and

FIG. 2 is a schematic electric circuit diagram of a lamp illumination device according to a preferred embodiment of the present invention.

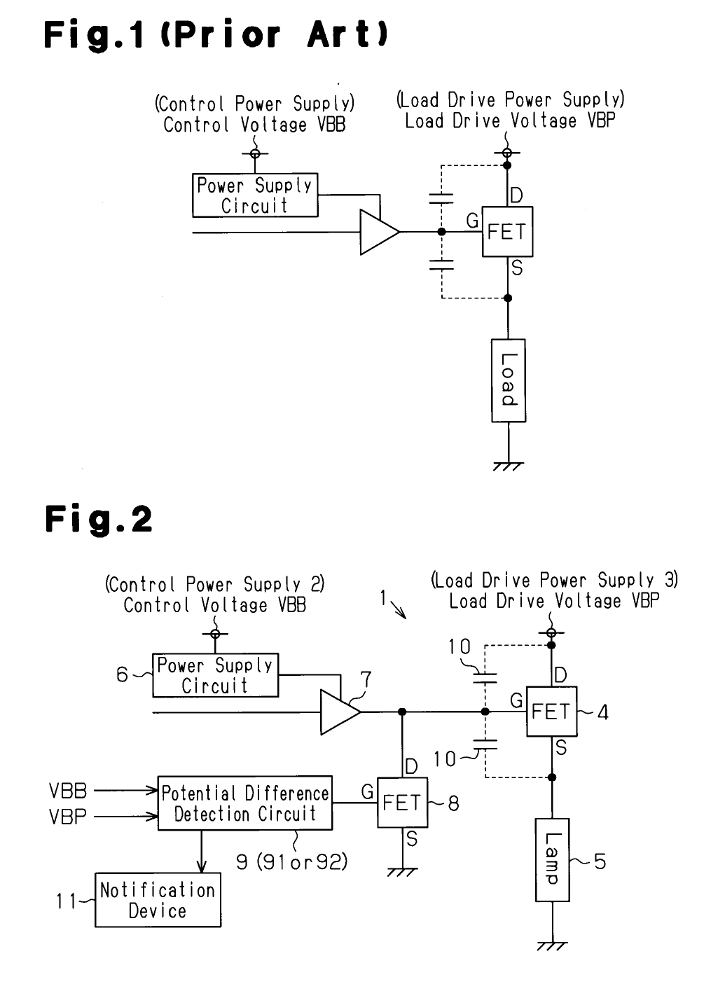

### DETAILED DESCRIPTION OF THE PREFERRED EMBODIMENTS

In the drawings, like numerals are used for like elements throughout.

A preferred embodiment of a load drive device, which is applied to a lamp illumination device, according to the present invention will now be discussed.

As shown in FIG. 2, a lamp illumination device 1 includes a switching element 4, which has an input system electrically connected to a control power supply 2 and an output system electrically connected to a load drive power supply 3. The switching element 4 is activated when voltage that is greater than or equal to a predetermined voltage, which is the minimum voltage required for activating the switching element 4, is applied to the input system of the switching element 4. This permits the load drive power supply 3 to supply power to a lamp 5 via the output system of the switching element 4 and turn on the lamp 5.

The voltage from the control power supply 2 applied to the lamp illumination device 1 is defined as a control voltage VBB. The voltage from the load drive power supply 3 applied to the lamp illumination device 1 is defined as a load drive voltage VBP.

It is assumed here that a control system power route connecting the control power supply 2 and the lamp illumination device 1 does not include any factor that would affect the output voltage of the control power supply 2. In this case, when the output voltage of the control power supply 2 varies from the minimum value (lower limit value) to the maximum value (upper limit value) of the rated output voltage, the control voltage VBB would converge within the appropriate voltage range as long as it is a normal voltage value. In the same manner, it is assumed here that a load drive system power route connecting the load drive power supply 3 and the lamp illumination device 1 does not include any factor that would affect the output voltage of the load drive power supply 3. In this case, when the output voltage of the load drive power supply 3 varies from the minimum value (lower limit value) to the maximum value (upper limit value) of the rated output voltage, the load drive voltage VBP would converge within the appropriate voltage range as long as it is a normal voltage value.

A power supply circuit 6 is arranged in the control system electrical route connecting the control power supply 2 to the input system of the switching element 4. The input system of the switching element 4 is electrically connected to an output circuit 7, which provides a control signal to the input system of the switching element 4.

The output circuit 7 includes a so-called charge pump (step-up circuit). The power supply circuit 6 applies a predetermined voltage to the output circuit 7. To turn on the lamp 5, the output circuit 7 generates a control signal having a higher voltage level than the voltage from the power supply circuit 6, that is, a voltage level suitable for activating the switching element 4. The control signal is provided to the input system of the switching element 4. When turning off the lamp 5, the output circuit 7 does not perform the step-up operation described above and provides the input system of the switching element 4 with a signal having an L level as the control signal. In other words, the L level control signal has a voltage level suitable for deactivating the switching element 4.

A switching element 8, which is discrete from the switching element 4, has a drain element electrically connected between the input system of the switching element 4 and the output circuit 7, specifically, the gate terminal of the switching element 4 and the output terminal of the output circuit 7. The switching element 8 further has a source terminal connected to ground and a gate terminal electrically connected to a potential difference detection circuit 9, which detects the potential difference between the control voltage VBB and the load drive voltage VBP.

The potential difference detection circuit 9 includes a subtraction circuit and a comparator (comparison circuit). When the potential difference between the control voltage VBB and the load drive voltage VBP is greater than a predetermined threshold value, the potential difference detection circuit 9 provides the gate terminal of the switching element 8 with a signal having an H level. When the potential difference is less than or equal to the predetermined threshold value, the potential difference detection circuit 9 provides the gate terminal of the switching element 8 with a signal having an L level. The switching element 8 is activated when the potential difference detection circuit 9 provides the gate terminal of the switching element 8 with a signal having an H level. This fixes the potential at the gate terminal of the switching element 4 at a level close to the ground level due to the drain voltage of the switching element 8.

The predetermined threshold value is set taking into consideration the electrical characteristics of the control power supply 2 and the load drive power supply 3 such as the rated output voltage. For example, the predetermined threshold value is set at a value obtained by subtracting the measurement value of the control voltage VBB when the control power supply 2 outputs the minimum value (lower limit value) of the rated output voltage from the measurement value of the load drive voltage VBP when the load drive power supply outputs the maximum value (upper limit value) of the rated output voltage. In the preferred embodiment, the subtraction circuit of the potential difference detection circuit 9 calculates the difference between the load drive voltage VBP and the control voltage VBB as a potential difference therebetween.

The operation of the lamp illumination device 1 will now be discussed.

### [Operation for Driving Load]

The operation for turning on the lamp 5 will first be discussed. In this case, the control power supply 2 applies normal control voltage VBB to the lamp illumination device 1, and the load drive power supply 3 applies normal load drive voltage VBP to the lamp illumination device 1. In this state, the switching element 4 is activated when a control signal boosted by the output circuit 7 is input to the input system of the switching element 4. This permits the load drive power supply 3 to supply power to the lamp 5 via the output system of the switching element 4 and turn on the lamp 5.

The potential difference detection circuit 9 inputs a signal having an L level to the gate terminal of the switching element 8 when the potential difference between the control voltage VBB and the load drive voltage VBP is less than or equal to the predetermined threshold value. This deactivates the switching element 8, and the potential at the gate terminal of the switching element 4 becomes dependent on the voltage level of the control signal from the output circuit. When driving the load, the control signal boosted by the output circuit 7 as described above is input to the input system of the switching element 4. Thus, the potential at the gate terminal of the switching element 4 becomes high. Accordingly, the switching element 4 is continuously activated until the output circuit 7 inputs a control signal having an L level to the input system of the switching element 4. During this period, the lamp 5 remains turned on.

### [Operation When Load Is Not Driven]

Next, the operation for turning off the lamp 5 will be discussed. In this case, the control power supply 2 applies normal control voltage VBB to the lamp illumination device 1, and the load drive power supply 3 applies normal load drive voltage VBP to the lamp illumination device 1 (in the same manner as in the load driving operation). In this state, the switching element 4 is deactivated when the output circuit 7 inputs a control signal having an L level to the input system of the switching element 4. This prohibits the load drive power supply 3 from supplying power to the lamp 5 via the output system of the switching element 4 and turns off the lamp 5.

The potential difference detection circuit 9 inputs a signal having an L level to the gate terminal of the switching element 8 when the potential difference between the control voltage VBB and the load drive voltage VBP is less than or equal to the predetermined threshold value. This deactivates the switching element 8, and the potential at the gate terminal of the switching element 4 becomes dependent on the voltage level of the control signal from the output circuit 7 (in the same manner as in the load driving operation). When the load is not driven, the output circuit 7 inputs a control signal having an L level to the input system of the switching element 4 as described above. Thus, the potential at the gate terminal of the switching element 4 becomes low. Accordingly, the switching element 4 is continuously deactivated until the output circuit 7 inputs a boosted control signal to the input system of the switching element 4. During this period, the lamp 5 remains turned off.

### [Operation When Control Voltage VBB Decreases]

The operation of the load drive device when the load drive power supply 3 is applying normal load drive voltage VBB to the lamp illumination device 1 but the control power supply 2 is not applying normal control voltage VBB to the lamp illumination device 1 will now be discussed. Here, a case in which the control voltage VBB is null or low for one reason or another will be discussed.

In this case, the potential difference between the control voltage VBB and the load drive voltage VBP becomes greater than the predetermined threshold value, and the potential difference detection circuit 9 inputs a signal having an H level to the gate terminal of the switching element 8. This activates the switching element 8. Thus, the potential at the gate terminal of the switching element 4 is fixed to a level close to the ground level without being dependent on the voltage level of the control signal from the output circuit 7. That is, the switching element 8 functions to prevent the existence of a stray capacitor 10 from increasing the potential at the gate terminal of the switching element 4. As a result, the switching element 4 is not activated. Accordingly, the load drive power supply 3 does not supply power to the lamp 5 via the output system of the switching element 4, and the lamp 5 remains turned off.

In the preferred embodiment, the switching element 4 serves as a load drive unit. The potential difference detection circuit 9 serves as a potential difference detection unit. The switching element 8 serves as a potential fixing unit.

The preferred embodiment has the advantages described below.

(1) When the control voltage VBB becomes null or low for one reason or another, the potential difference between the control voltage VBB and the load drive voltage VBP becomes greater than the predetermined threshold value. This fixes the potential at the control system electrical route connecting the control power supply 2 to the input system of the switching element 4 at a level that prohibits the output system of the switching element 4 from turning on the lamp 5. Thus, the switching element 8 functions to prevent the existence of the stray capacitor 10 from increasing the potential at the control system electrical route. Accordingly, the occurrence of a phenomenon caused by the existence of the stray capacitor 10 is prevented.

(2) The structure of the prior art differs from the structure of the preferred embodiment in that it does not include the switching element 8 and the potential difference detection circuit 9. Thus, when using the lamp 5 as the electrical load in the prior art structure, if the control voltage VBB becomes null or low, the existence of the stray capacitor 10 may momentarily turn on the lamp 5. Comparatively, the structure of the preferred embodiment includes the switching element 8 and the potential difference detection circuit 9. Thus, as described in advantage (1), the lamp 5 is never turned on regardless of the existence of the stray capacitor 10. This prevents unexpected illumination of the lamp 5, for example, in a vehicle in which the lamp illumination device 1 is installed and extends the life of the lamp 5.

It should be apparent to those skilled in the art that the present invention may be embodied in many other specific forms without departing from the spirit or scope of the invention. Particularly, it should be understood that the present invention may be embodied in the following forms.

A notification device 11, which issues a notification of the detection result of the potential difference detection circuit 9, may be electrically connected to the potential difference detection circuit 9. In this case, when the potential difference between the control voltage VBB and the load drive voltage VBP exceeds a predetermined threshold value, in addition to the potential difference detection circuit 9 providing the gate terminal of the switching element 8 with a signal having an H level, the notification device 11 issues a notification indicating that the control voltage VBB is null or low. The notification signal from the notification device 11 allows for measures to be promptly taken to return the null or low control voltage VBB to the normal control voltage VBB. In other words, the user being assisted by the notification device 11 may readily return the lamp illumination device to the normal state of use.

The notification device 11 may issue a visual notification, which uses a display such as a monitor, or an audio notification, which uses a sound generator such as a buzzer or speaker. The notification device 11 may also issue a notification through vibration by using a vibrator. Further, each of these devices may be used in combination.

The notification device 11 of the above modification may perform a notification operation in a stepped manner in accordance with the level of the potential difference between the control voltage VBB and the load drive voltage VBP. For example, the “predetermined threshold value” of the preferred embodiment may be set as a “first threshold value” and a “second threshold value” in an ascending order. In this case, when the potential difference detected by the potential difference detection circuit 9 reaches the “first threshold value,” the notification device 11 performs a first notification operation. However, at this stage, the potential difference detection circuit 9 does not output a signal having an H level to the gate terminal of the switching element 8. Rather, at that stage, the potential difference detection circuit 9 outputs a signal having an L level. Then, when the potential difference detected by the potential difference detection circuit 9 reaches the “second threshold value,” the notification device 11 performs a second notification operation. At this stage, the potential difference detection circuit 9 starts to output a signal having an H level to the gate terminal of the switching element 8. This allows the user to be aware of a decrease in the control voltage VBB at an initial stage in which it has not yet reached a bottom value.

Such stepped notification operations are, of course, not limited to two stages and may be performed in a stepped manner in three or more stages. Such frequent notification operations allow the user to be aware of the present situation (potential difference) so that the proper measures can be taken.

When activating the switching element 4 and supplying power to the lamp 5 from the load drive power supply via the output system of the switching element 4, if the load drive voltage VBP is null or low, the probability of the lamp 5 being turned on is low. In other words, the lamp 5 would be turned off when it should be turned on. In such a case, the notification device 11 of the above modification may issue a notification indicating that the load drive voltage VBP is low. Here, in a manner reversed from the preferred embodiment, the subtraction circuit of the potential difference detection circuit 9 subtracts the load drive voltage VBP from the control voltage VBB to obtain the potential difference therebetween.

At least either one of a control voltage detection unit 91 (control voltage monitor unit), which detects (monitors) the control voltage VBB, and a load drive voltage detection unit 92 (load voltage monitor unit), which detects (monitors) the load drive voltage VBP, may be used in lieu of or in addition to the potential difference detection circuit 9. Specifically, the present invention may be embodied in the load drive device described in the following paragraphs (a) to (f).

(a) A load drive device including the control voltage detection unit 91, which detects the control voltage VBB, but does not include the load drive voltage detection unit 92, which detects the load drive voltage VBP, and the potential difference detection circuit 9.

(b) A load drive device including the load drive voltage detection unit 92, which detects the load drive voltage VBP, but does not include the control voltage detection unit 91, which detects the control voltage VBB, and the potential difference detection circuit 9.

(c) A load drive device including the control voltage detection unit 91, which detects the control voltage VBB, and the load drive voltage detection unit 92, which detects the load drive voltage VBP, but does not include the potential difference detection circuit 9.

(d) A load drive device including the potential difference detection circuit 9 and the control voltage detection unit 91, which detects the control voltage VBB, but does not include the load drive voltage detection unit 92, which detects the load drive voltage VBP.

(e) A load drive device including the potential difference detection circuit 9 and the load drive voltage detection unit 92, which detects the load drive voltage VBP, but does not include the control voltage detection unit 91, which detects the control voltage VBB.

(f) A load drive device including the potential difference detection circuit 9, the control voltage detection unit 91, which detects the control voltage VBB, and the load drive voltage detection unit 92, which detects the load drive voltage VBP.

In the load drive device described in any one of paragraphs (a), (c), (d), and (f), the control voltage detection unit (control voltage monitor unit) functions in the following manner when the control power supply 2 cannot apply the normal control voltage VBB to the lamp illumination device 1 for one reason or another. The control voltage detection unit 91 allows for the switching element 8 to be controlled so that the potential at the gate terminal of the switching element 4 is fixed at a level close to the ground level in the same manner as the preferred embodiment. Further, the control voltage detection unit 91 allows for the notification device 11 of the above modification to issue a notification indicating that the control voltage VBB is decreasing. In this case, the notification device 11 may issue notifications indicating that the control voltage VBB is decreasing in a stepped manner.

In the load drive device described in any one of paragraphs (b), (c), (e), and (f), the load drive voltage detection unit (load drive voltage monitor unit) functions in the following manner when the load drive power supply 3 cannot apply the normal load drive voltage VBP to the lamp illumination device 1 for one reason or another. The load drive voltage detection unit 92 allows for the switching element 8 to be controlled so that the potential at the gate terminal of the switching element 4 is fixed at a level close to the ground level in the same manner as the preferred embodiment. Further, the load drive voltage detection unit 92 allows for the notification device 11 of the above modification to issue a notification indicating that the load drive voltage VBP is decreasing. In this case, the notification device 11 may issue notifications indicating that the load drive voltage VBP is decreasing in a stepped manner.

In the preferred embodiment, the control power supply 2 applies the control voltage VBB to the lamp illumination device 1, and the load drive power supply 3 applies the load drive voltage VBP to the lamp illumination device 1. Thus, the load is driven by two different power supplies. However, the present invention may also be embodied in a load drive device that drives a load with a single power supply. In this case, the single power supply supplies power through two systems. Specifically, a first system applies the control voltage VBB to the lamp illumination device 1, and a second system applies the load drive voltage VBP to the lamp illumination device 1.

In the preferred embodiment, the load drive device is embodied in the lamp illumination device 1. However, the electrical load that is driven may be, for example, a motor (electric motor) instead of a lamp. Such type of a motor drive device generally drives a motor with a so-called half bridge circuit, which uses two switching elements such as FETs, or a so-called full bridge circuit (H-bridge circuit), which uses four switching elements such as FETs.

For instance, when the present invention is applied to such a motor drive device, each switching element (load drive unit) of the bridge circuit is provided with a single potential fixing unit such as the switching element 8 of the preferred embodiment. In this case, when the potential difference detected by the potential difference detection circuit 9 becomes greater than a predetermined threshold value, the potential fixing units are all simultaneously activated. As a result, the potentials at the control system electrical routes respectively connecting the load drive units and the control power supply are simultaneously fixed at a level that prohibits the output system of each load drive unit from producing rotation with the motor. That is, the potential fixing units each function to simultaneously prevent the potential of each control system electrical route from being decreased by the stray capacitor existing near each load drive unit. This ensures that the occurrence of a phenomenon (in this case, torque being produced notwithstanding the fact that it may be too small to produce rotation) caused by the existence of a stray capacitor is prevented.

The present examples and embodiments are to be considered as illustrative and not restrictive, and the invention is not to be limited to the details given herein, but may be modified within the scope and equivalence of the appended claims.

What is claimed is:

1. A load drive device for driving an electrical load with a control power supply and a load drive power supply, the load drive device comprising:
a load drive unit including an input system electrically connectable to the control power supply and an output system electrically connectable to the load drive power supply, in which the load drive unit supplies the electrical load with load drive voltage from the load drive power supply via the output system when the control power supply applies control voltage to the input system;
a potential difference detection unit which detects a potential difference between the control voltage and the load drive voltage; and
a potential fixing unit which fixes a potential at a control system electrical route, connecting the control power supply and the input system of the load drive unit, to a prohibition level that prohibits the output system of the load drive unit from driving the electrical load when the potential difference detected by the potential difference detection unit exceeds a predetermined threshold value.

2. The load drive device according to claim 1, wherein the potential fixing unit fixes the potential at the control system electrical route to the prohibition level when the detected potential difference exceeds the predetermined threshold value in a state in which the control voltage is lower than the load drive voltage.

3. The load drive device according to claim 1, further comprising:
a notification device electrically connected to the potential difference detection unit, in which the notification device issues a notification indicating information related to the potential difference between the control voltage and the load drive voltage.

4. The load drive device according to claim 3, wherein the notification device performs a notification operation in a stepped manner in accordance with the level of the potential difference between the control voltage and the load drive voltage.

5. The load drive device according to claim 4, wherein:
when the level of the potential difference reaches a first threshold value, the notification device performs a first notification operation and the potential difference detection unit outputs a signal having a first level to the input system of the load drive unit; and
when the level of the potential difference reaches a second threshold value, the notification device performs a second notification operation and the potential difference detection unit outputs a signal having a second level to the input system of the load drive unit.

6. The load drive device according to claim 3, wherein the notification device issues a notification indicating that the load drive voltage is low when the detected potential difference exceeds the predetermined threshold value in a state in which the load drive voltage is lower than the control voltage.

7. A load drive device for driving an electrical load with a control power supply and a load drive power supply, the load drive device comprising:
a load drive unit including an input system electrically connectable to the control power supply and an output system electrically connectable to the load drive power supply, in which the load drive unit supplies the electrical load with load drive voltage from the load drive power supply via the output system when the control power supply applies control voltage to the input system;
a control voltage detection unit which detects the control voltage; and
a potential fixing unit which fixes a potential at a control system electrical route, connecting the control power supply and the input system of the load drive unit, to a prohibition level that prohibits the output system of the load drive unit from driving the electrical load when the control voltage detected by the control voltage detection unit is less than a normal control voltage.

8. The load drive device according to claim 7, further comprising:
a notification device electrically connected to the control voltage detection unit, in which the notification device issues a notification indicating that the control voltage is decreasing.

9. The load drive device according to claim 7, further comprising:
a load drive voltage detection unit which detects the load drive voltage,
wherein the notification device further issues a notification indicating that the load drive voltage is decreasing.

10. A load drive device for driving an electrical load with a control power supply and a load drive power supply, the load drive device comprising:
a load drive unit including an input system electrically connectable to the control power supply and an output system electrically connectable to the load drive power supply, in which the load drive unit supplies the electrical load with load drive voltage from the load drive power supply via the output system when the control power supply applies control voltage to the input system;
a load drive voltage detection unit which detects the load drive voltage; and
a notification device which issues a notification indicating that the load drive voltage is low when the load drive voltage detected by the load drive voltage detection unit is lower than a normal load drive voltage.

11. The load drive device according to claim 10, further comprising:
a control voltage detection unit which detects the control voltage,
wherein the notification device further issues a notification indicating that the control voltage is decreasing.
